(19) United States
(12) Patent Application Publication
(10) Pub. No.: US 2014/0353159 A1
(43) Pub. Date: Dec. 4, 2014

(54) ELECTROCHEMICAL METHOD OF LITHIUM IRON ARSENIC SUPERCONDUCTOR PREPARATION

(71) Applicants: The Ohio State University, Columbus, OH (US); Centrum vedecko-technickych Informacii SR, Bratislava (SK); Technicka univerzita v Kosiciach, Kosice (SK)

(72) Inventors: Milan Majoros, Columbus, OH (US); Maria Kanuchova, Kosice (SK); Michael D. Sumption, Newark, OH (US); Edward W. Collings, Columbus, OH (US)

(21) Appl. No.: 13/909,493

(22) Filed: Jun. 4, 2013

(51) Int. Cl. H01L 39/24; C25D 17/00

(52) U.S. Cl. CPC H01L 39/24; C25D 17/00
USPC 205/51; 204/243.1

(57) ABSTRACT

A method and apparatus for producing lithium iron arsenic superconductor materials. An example of the method comprises providing at least one cathode comprised of iron arsenic, providing at least one anode comprised of a chemically inert material, placing the at least one cathode and at least one anode into an electrolyte comprised of molten lithium chloride and/or lithium bromide, and applying a voltage such that electrical current flows between the at least one anode and the at least one cathode.

### BACKGROUND AND SUMMARY OF THE INVENTION

Exemplary embodiments of the present invention relate generally to an electrochemical method of producing a lithium iron arsenic superconductor.

Superconductors are those materials that below certain temperature and magnetic field levels, exhibit zero electrical resistance. In non-superconducting materials, when electrical current is passed through the material, the resistance of the material causes a voltage to appear in the material. This voltage in conjunction with the electrical current results in a power loss which produces heat.

When the material is a wire or other structure intended to conduct electricity from one location to another (conductors), the voltage that may appear, the power loss, and the resulting heat generated are frequently undesirable. In order to decrease the resistance of a length of given material (for example, copper) without changing the environment in which the material operates, the cross sectional area must be increased. Therefore, in order to decrease the amount of resistance in a conductor, reducing the amount of voltage appearing along the length of such a conductor and the resulting heat generation, that conductor must be made larger in cross sectional area. As the cross sectional area is increased, the volume of conductor material also increases along a given length of such a conductor. Because conductors are often materials such as copper, aluminum, silver, or gold, conductors with larger cross-sectional areas may be costly due to the relatively high value of such materials.

A second negative impact from the requirement of larger conductors may be the physical size of the conductors. Extremely high currents may require large cross-sectional conductor areas to carry those currents without producing excessive amounts of heat. The requirement of such large cross sectional areas may result in undesirably large or heavy devices. As a result, superconductors may be used to facilitate increases in efficiency by allowing fewer losses due to heat and the use of smaller and lighter conductors.

Power generation and transmission, power storage, and highly efficient electric motors are examples of applications which may benefit from the use of superconductors. Superconductors may also be used to form highly efficient electromagnets. A familiar example of such an application may be found in magnetic levitation trains.

In addition to using superconductors to form electromagnets, another characteristic of superconductors related to magnetism is their exclusion of magnetic fields, known as the Meissner effect. This characteristic may be exploited to produce highly sensitive measurement and detection devices. Such devices are frequently used in the medical research field to perform such functions as mapping the magnetic fields of the brain. Other examples of measurement devices that use superconductors are highly sensitive thermometers used in scientific research.

As a result of the applications discussed and others, superconductors are increasingly in use and cost-effective methods of producing such superconducting materials are needed.

A known method of producing superconductor materials involved mixing the raw materials required to form the superconductors into a homogeneous mixture. After a mixing operation, the mixture is heated for several hours at high temperatures in a calcination process. The material may be required to be reground, remixed, and re-calcinated several times to produce a sufficiently homogenous mixture. After the mixture is sufficiently homogeneous, the mixture may be compacted into pellet shapes and sintered. Sintering is a well documented process which involves forming materials into a shape under sufficient pressure such that they remain in close contact so that the particles diffuse into one another at the atomic level. The sintering process also requires high temperatures and exposure to a tightly controlled environment when implemented as part of a solid-state reaction process producing superconductor materials. Such factors are crucial to produce a material with the desired superconducting characteristics.

Oxypnictide materials such as Lithium Iron Arsenic (LiFeAs) compounds are known for the complexity of their methods of preparation. Forming LiFeAs compounds using a solid-state reaction method as described above requires a solid-state reaction at high temperatures (740-1050° C.) for long time periods (24-60 hours). Such a solid-state reaction process is both time and energy intensive due to the high temperatures and extended times at such temperatures required during the calcination and sintering processes.

LiFeAs crystallizes in the tetragonal PbFCl type unit cell (P4/nmm) with a=3.7914 Å and c=6.364 Å. The Fe2As2 charge-carrying layers are alternatively stacked along the c-axis with nominal double layers of Li ions. Unlike the known isoelectronic undoped intrinsic FeAs compounds, LiFeAs does not show any spin-density wave behavior but exhibits superconductivity at ambient pressures without chemical doping. It has a superconducting transition temperature (Tc) of 18 K with electron-like carriers and a very high 0 K upper critical magnetic field, Bc2(0), of greater than 80 Teslas making the compound suitable for many high magnetic field applications at cryogenic temperatures.

As reported by Chen et al. [Chen N., Qu S., Li Y., Liu Y., Zhang R., and Zhao H. 2010 J. Appl. Phys. 107 09E123] advantage may be taken of the small atomic radius of Li to enable an electrochemical method to be used to insert Li into the precursor FeAs to form LiFeAs at room temperature. In the previously reported method, an electrode (the cathode) was formed by painting a gelatinous mixture of powdered FeAs and acetylene black dissolved in N-methyl-pyrrolidone (NMP) onto a clean Copper foil which was then heated at 60° C. to fully drive off the NMP. The electrode was then placed under pressure to densify the surface layer of FeAs. Once the desired densification was achieved the electrode was dried in a vacuum oven at 120° C. for 2 hours before cooling it slowly down to room temperature. The electrode was then punched into a disk shape 8 mm in diameter suitable for use as the cathode in an electrolytic cell. The anode was a lithium film attached to the bottom of the electrolytic cell. The electrolyte was a liquid mixture of ethyl carbonate, diethyl carbonate, lithium hexafluorophosphate, and ethyl methyl carbonate in equal amounts by volume. The use of a closed cell ensured protection of the FeAs electrode from moisture, oxygen, and nitrogen in air.

In an embodiment of the current invention, LiFeAs may be prepared using an electrolysis method in an open air electrolytic cell. In such a method, a cathode formed from an iron arsenic compound is suspended in an electrolyte along with an anode formed from an inert material. A direct current, provided by a substantially constant voltage, is then passed between the anode and cathode, causing Lithium to be deposited on the cathode, resulting in a LiFeAs cathode material. In one such embodiment, the electrolyte may be molten lithium chloride (LiCl).

In a second embodiment of the invention, a cathode formed from an iron arsenic compound is suspended in an electrolyte solution comprised of molten lithium chloride mixed with potassium chloride. A direct current, provided by a substantially constant voltage, is passed between an anode formed from an inert material and the cathode. The result is a deposit of lithium on the cathode, resulting in a LiFeAs cathode material.

In a third embodiment of the invention, a cathode is formed from an iron arsenic compound, which is suspended in an electrolyte solution comprised of molten lithium bromide (LiBr). As with the first and second embodiments, a direct current, provided by a substantially constant voltage, is passed between an anode formed from an inert material and the cathode. The result is a deposit of lithium on the cathode, resulting in the desired LiFeAs formation at the cathode.

A fourth embodiment of the invention uses the same configuration of iron arsenic cathode, inert anode, and a direct current power supply adapted to provide a substantially constant voltage. In the fourth embodiment, the electrolyte used is a mixture of molten lithium bromide mixed with lithium chloride. When subjected to the direct current power supply, lithium is deposed on the cathode, resulting in the formation of LiFeAs at the cathode.

The disclosed embodiments are unlike previous methods in that they do not require a Li anode. The disclosed embodiments also may be performed in open air in an electrolytic cell comprised of electrodes immersed in a molten salt electrolyte, which makes it very suitable for practical large-scale applications.

In addition to the novel features and advantages mentioned above, other benefits will be readily apparent from the following descriptions of the drawings and exemplary embodiments.

### BRIEF DESCRIPTION OF THE DRAWINGS

FIG. 1 is a diagram of an exemplary embodiment of the electrochemical process and system of the invention.

### DETAILED DESCRIPTION OF EXEMPLARY EMBODIMENT(S)

Exemplary embodiments of the present invention are directed to a method of producing a LiFeAs superconductor material using an electrochemical process which may be performed in an open air environment.

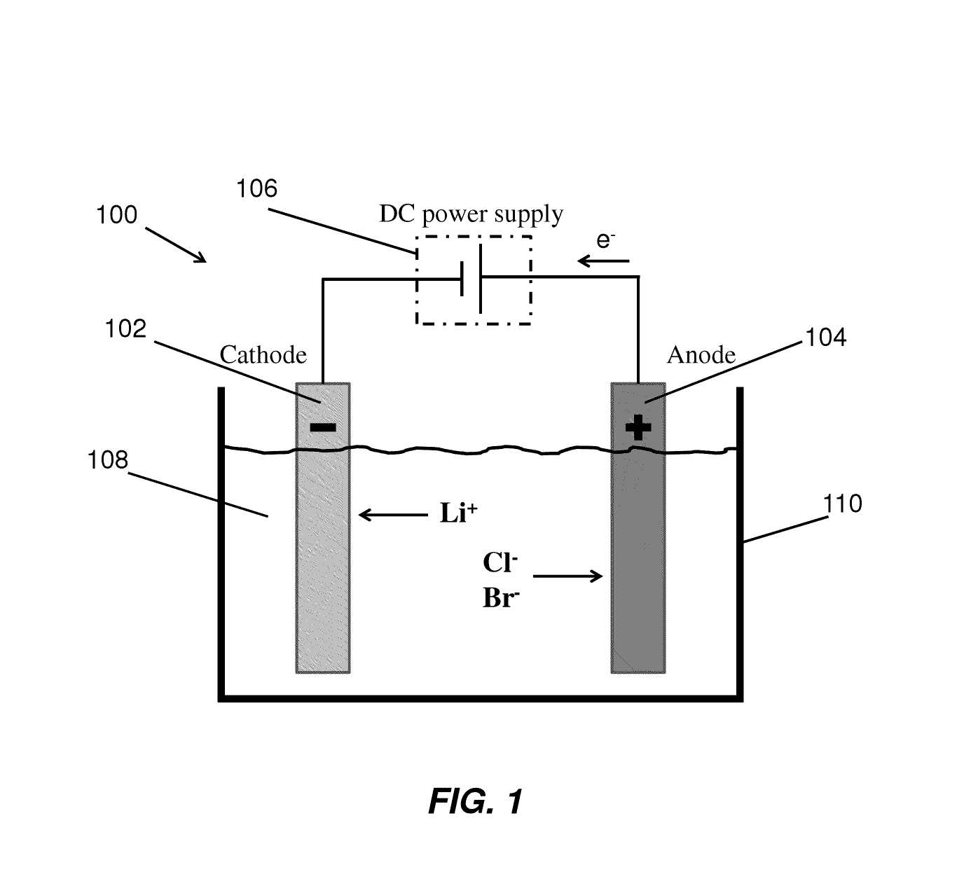

Referring to FIG. 1, an electrochemical cell 100 for the preparation of LiFeAs comprises a cathode 102, an anode 104, a direct current power supply 106 adapted to provide a substantially constant voltage, an electrolyte 108, and a vessel 110 for containing the electrolyte. Unlike known methods of producing LiFeAs, embodiments of the invention do not require the formation process to be performed in a sealed chamber.

In embodiments of the invention, the anode 104 may be formed from non-reactive materials. Examples of such materials comprise stainless steel, graphite, platinum, gold, and other noble metals.

Cathode 102 is comprised of iron arsenic (FeAs). Cathodes 102 may be formed into shapes that allow convenient mounting in the reaction vessel. In addition, the cathode 102 used in embodiments of the invention may be shaped such that the resulting LiFeAs material may readily be formed into the shape required in the desired superconductor application. Examples of such shapes may comprise pellets, foils, rods, bars, strips, films, wire, and various other geometric shapes.

An exemplary embodiment of cathode 102 may have a surface area in contact with the electrolyte solution 108 that is approximately equivalent to that of the anode 104. However, in some embodiments, the respective surface areas of a cathode and anode in contact with the electrolyte solution may be different.

An example of the power supply 106 in an embodiment of the invention may be configured such that it produces a substantially constant voltage output level equal to about 6 volts DC. The current output of the power supply may be about 0.2 amps or less in certain exemplary embodiments of the invention. Other voltage levels and current limits may be used in embodiments of the invention where such voltage and current levels may be optimized based on the cathode, anode, vessel size, and vessel shape. For example, an embodiment that has cathode and anode structures that have large surface areas or are formed from multiple structures may perform optimally at higher or lower voltage and current levels than those listed above. Also, while exemplary embodiments may refer to the use of a substantially constant voltage, a variable voltage may alternatively be used in some embodiments.

Examples of a salt electrolyte include lithium chloride (LiCl), lithium bromide (LiBr), LiCl mixed with potassium chloride (KCl), and LiBr mixed with LiCl. Combinations including any of the aforementioned materials are also examples of salt electrolytes. In addition, examples include other mixtures comprising lithium.

In a first embodiment of the current invention, LiFeAs may be prepared by suspending a cathode 102 formed from an iron arsenic compound in an electrolyte solution 108 comprised of molten LiCl, which has a melting point of approximately 605° C. An anode 104 formed from an inert material is also suspended in the electrolyte solution. A power supply 106 is connected between the cathode and anode and is adapted to provide a substantially constant voltage such that a direct current flows through the electrical circuit formed by the anode, electrolyte, and the cathode, causing Lithium to be deposited on the cathode. The result of such a deposit is a LiFeAs cathode material. In this embodiment, chlorine may be released at the anode surface.

In a second embodiment of the current invention, LiFeAs may be prepared by suspending a cathode 102 formed from an iron arsenic compound in an electrolyte solution 108 comprised of molten lithium chloride mixed with molten potassium chloride to form a LiCl—KCl binary system electrolyte solution. The eutectic composition of 41.8 mol % KCL and 58.2 mol % LiCl has a melting point as low as 352° C. In such an electrolyte solution, lithium chloride may function as the cell feed and the potassium chloride may function as the solvent and supporting electrolyte. Among the common alkali and alkaline-earth chlorides, potassium chloride also exhibits a decomposition potential that is more extreme than lithium chloride and has a poor alloying ability with lithium.

A power supply 106 is connected between an iron arsenic cathode 102 and an anode 104 formed from inert material as previously described. A direct current, provided by a substantially constant voltage, is then passed through the electrical circuit formed by the anode, electrolyte, and the iron arsenic cathode. The result is a deposit of lithium on the cathode, resulting in a LiFeAs cathode material. As with the previously described embodiment, chlorine may be released at the anode surface. Characteristics of the molten LiCl—KCl binary system electrolyte, including its lower melting point when combined in proportions approaching its eutectic point, are such that this embodiment may require less energy than the other disclosed embodiments of the invention and may thus be a preferred embodiment.

In a third embodiment of the invention, LiFeAs may be prepared by suspending a cathode 102 formed from an iron arsenic compound in an electrolyte solution 108 comprised of molten LiBr, which has a melting point of approximately 552° C. As with the first and second embodiments, a direct current power supply 106 is connected between an iron arsenic cathode 102 and an anode 104 formed from inert material as previously described. A substantially constant voltage is applied that causes a direct current to flow through the electrical circuit formed by the anode formed from an inert material, the electrolyte solution, and the cathode. The result is a deposit of lithium on the cathode, resulting in the desired LiFeAs formation at the cathode. The process is similar to that of the first embodiment except that liquid bromine ions are released at the anode. Lithium bromide has a lower melting point than that of lithium chloride, which may provide an advantage with respect to the lithium chloride electrolyte of the first embodiment.

An affinity of lithium for molten lithium chloride manifests itself in a thin, protective lithium chloride coat on the cathode 102. The integrity of this layer holds even for lithium globules of 1 cm-size. Its importance in molten lithium chloride electrolysis lies not just in the protection it affords from the atmosphere, but also from chlorine gas formed at the anode and transported by convection throughout the electrolyte. The aforementioned embodiment cannot provide the protective lithium chloride coat and therefore may be less advantageous when compared to other disclosed embodiments.

In a fourth embodiment of the invention, LiFeAs may be prepared by suspending a cathode 102 formed from an iron arsenic compound in an electrolyte solution 108 comprised of molten lithium bromide mixed with 10-15% lithium chloride. The eutectic composition of 13% lithium chloride has a melting point of approximately 520° C.

A power supply 106 is connected between an iron arsenic cathode 102 and an anode 104 formed from inert material as previously described. A direct current, provided by a substantially constant voltage, is then passed through the electrical circuit formed by the anode, electrolyte, and the iron arsenic cathode. The result is a deposit of lithium on the cathode, resulting in a LiFeAs cathode material. The lower melting point of the electrolyte in this embodiment may provide may provide an advantage with respect to the lithium chloride electrolyte of the first embodiment and the lithium bromide electrolyte of the third embodiment. As with third embodiment, liquid bromine ions are released at the anode.

Other exemplary embodiments may be comprised of variations of the aforementioned examples. For instance, any embodiment of the present invention may include any of the optional or preferred features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention. It is the intention, therefore, to limit the invention only as indicated by the scope of the claims.

What is claimed is:

1. A method of producing a Lithium Iron Arsenic (LiFeAs) coating on an electrode comprising the steps of:
providing at least one cathode;
providing at least one anode;
placing said at least one cathode and said at least one anode in a salt electrolyte; and
applying a voltage such that electrical current flows between said at least one anode and said at least one cathode;
wherein LiFeAs is formed.

2. The method of claim 1 wherein said electrolyte is comprised of molten lithium chloride.

3. The method of claim 1 wherein said electrolyte is comprised of molten lithium chloride mixed with potassium chloride.

4. The method of claim 3 wherein said electrolyte mixture is comprised of 58.2 mol lithium chloride and 41.8 mol % potassium chloride.

5. The method of claim 1 wherein said electrolyte is comprised of molten lithium bromide.

6. The method of claim 1 wherein said electrolyte is comprised of molten lithium bromide mixed with lithium chloride.

7. The method of claim 6 wherein said lithium chloride comprises 10-15% of the electrolyte.

8. The method of claim 1 wherein said at least one cathode is comprised of iron arsenic.

9. The method of claim 1 wherein said at least one anode is comprised of an inert material.

10. The method of claim 1 wherein:
the electrical current is generated by a 6 volt, direct current source; and
said current is about 0.2 amps or less.

11. An system for producing a lithium iron arsenic (LiFeAs) coating on an electrode, comprised of:
at least one cathode connected to a negative output connection of a power supply;
at least one anode connected to a positive output connection of said power supply; and
an electrolyte in which said at least one cathode and said at least one anode are in electrical contact;
wherein said electrolyte is in an open air vessel.

12. The system of claim 11 wherein said power supply is a direct current power supply configured to provide a voltage of about 6 volts DC.

13. The system of claim 12 wherein said direct current power supply is further configured to provide an output current of about 0.2 amps or less.

14. The system of claim 11 wherein said at least one cathode is comprised of iron arsenic.

15. The system of claim 11 wherein said at least one anode is comprised of an inert material.

16. The system of claim 11 wherein said electrolyte solution is comprised of molten lithium chloride.

17. The system of claim 11 wherein said electrolyte solution is comprised of molten lithium chloride mixed with potassium chloride.

18. The system of claim 11 wherein said electrolyte solution is comprised of molten lithium bromide.

19. The system of claim 11 wherein said electrolyte solution is comprised of molten lithium bromide mixed with lithium chloride.

20. A method of producing a Lithium Iron Arsenic (LiFeAs) coating on an electrode comprising the steps of:
providing at least one cathode comprised of iron arsenic;
providing at least one anode comprised of a chemically inert material;
providing an electrolyte comprised of molten lithium chloride, molten lithium bromide, or a mixture comprising molten lithium chloride with potassium chloride or molten lithium bromide with lithium chloride;
placing said at least one cathode and said at least one anode in said electrolyte;
providing a direct current power supply; and
applying a voltage such that said direct current flows between said at least one anode and said at least one cathode;
wherein LiFeAs is formed.
